(19) United States
(12) Patent Application Publication
(10) Pub. No.: US 2023/0100378 A1
(43) Pub. Date: Mar. 30, 2023

(54) SWITCHING CONTROL CIRCUITS AND METHOD OF ACTUATING A SWITCH HAVING REDUCED CONDUCTED EMI

(71) Applicant: STELPRO DESIGN INC, Saint-Bruno-de-Montarville (CA)

(72) Inventors: Maxime CHAMPAGNE, Varennes (CA); Jimmy LEMIRE, Trois-Rivières (CA); Guillaume SIMARD, Laval (CA)

(73) Assignee: STELPRO DESIGN INC., Saint-Bruno-de-Montarville (CA)

(21) Appl. No.: 17/956,356

(22) Filed: Sep. 29, 2022

Related U.S. Application Data
(60) Provisional application No. 63/249,882, filed on Sep. 29, 2021.

(51) Int. Cl. H02M 1/08; G01R 19/175; H02M 1/00

(52) U.S. Cl. CPC H02M 1/083; G01R 19/175; H02M 1/0058

(57) ABSTRACT

The present disclosure provides a control circuit to power a load, the circuit generally comprising a first switch such as a TRIAC to switch on and off and power the load based upon user demand. The circuit is also comprised of a second connected in parallel with the TRIAC, the second switch switching to a conducting state at a zero-crossing of the source before becoming completely saturated. Once the second switch is saturated, the first switch switches from a non-conducting state to a conducting state, which minimizes conducted EMI generated in the circuit.

### CROSS REFERENCE TO RELATED APPLICATION

The present application claims priority to U.S. Provisional Application No. 63/249,882, entitled “SWITCHING CONTROL CIRCUITS AND METHOD OF ACTUATING A SWITCH HAVING REDUCED CONDUCTED EMI” filed on Sep. 29, 2021, the contents of which are incorporated herein by reference in their entirety.

### FIELD

The invention relates to the field of line thermostats, and more specifically to an electronic switching control circuit having reduced conducted electromagnetic interference.

### BACKGROUND

Control devices, and thermostats specifically, have been undergoing a number of changes over the last few years. The introduction of smart thermostats has changed the thermostat landscape by offering users the ability to change the temperature remotely, use existing wiring to power complex loads, etc.

However, there is also a need to provide 2-wire line voltage thermostats that are compatible with electrical heating system such as power heavy convection heaters. The control circuits for such thermostats are preferably compatible with both low and high current thermostats.

Ultimately, these control circuits are comprised of a switch, typically a TRIAC switch, and activating said switch, if done improperly, will emit a large amount of conducted electromagnetic interference (EMI). The conducted EMI must be kept below certain governmental norms.

Inventions such as U.S. Pat. No. 9,608,507 (Houde), 9,264,035 (Tousignant) and U.S. patent application Ser. No. 16/699,473 (Champagne) have tried to produce a variety of control circuits for thermostats to reduce the conducted EMI.

Specifically, Houde conceived a low power and low EMI power stealing circuit for such a control device. Indeed, Houde teaches a voltage detector that monitors the zero-crossing of the line voltage. After the zero-crossing is detected, a signal is sent resulting in the actuation of a charge switch, which diverts power away from a TRIAC switch and into a charge storage device. From the charge storage device, the charge is then transferred to energize the thermostat's control circuit. In other words, power stealing occurs after the zero-line crossing detection and with the use of a secondary charge switch. Once the charge storage device is fully charged, a signal is sent to transfer the line voltage to another switch, which controllably lowers the line voltage towards zero volts. Once the line voltage approaches zero volts, the TRIAC is activated and brought into a conducting state. As the line voltage is already near zero, the voltage drop across the terminals of the TRIAC is not significant, which results in lower EMI. In other words, power stealing occurs after a zero-crossing detection, before the activation of the TRIAC and without the use of a primary slow linear switch.

Meanwhile, Tousignant teaches a power supply for use in a thermostat having reduced EMI. The circuit is comprised of a zero-crossing detector that monitors the line voltage and activates a TRIAC after such a zero-crossing. A MOSFET gate driving circuit is disclosed to soften the voltage transition from the charging element to the TRIAC, which reduces the voltage drop and correspondingly the EMI generated by such a circuit.

Finally, Champagne teaches a plurality of switching control circuits; however, each one of the circuits disclosed utilizes solely a TRIAC switch and drive circuit to activate the TRIAC before or around the zero-crossing. None of the solutions described in Champagne teach nor suggest the use of a slow linear switch that is activated first before the activation of the TRIAC to soften a current change di/dt and therefore reduce conducted EMI.

Unfortunately, there are still deficiencies in the described inventions. More specifically, there is a need for a control circuit for a low-current thermostat, capable of actuating a first slow linear switch before a zero-crossing of the power source before the actuation of a second TRIAC switch, which can reduce conducted EMI.

### SUMMARY

In an aspect, the present disclosure provides a control circuit to control power to a load, comprising: a first switch connected to a power source, the switch configured to switch from a first non-conducting state to a second conducting state; an energy bank electrically connected to the first switch, the energy bank to store energy and power a device when the first switch is in the second conducting state; a zero-crossing (ZC) detection circuit electrically connected to detect a zero-crossing of the power source, a second switch in parallel electrical connection with the first switch, the slow linear switch activated after the zero-crossing of the power source.

In another aspect, the present disclosure provides a method of activating a first switch, the steps comprising: detecting a zero-crossing of a power source; actuating a second switch after the zero-crossing of the power source; and, actuating the first switch after the second switch is completely saturated to reduce conducted electromagnetic interference of a control circuit.

### BRIEF DESCRIPTION OF THE DRAWINGS

The following figures serve to illustrate various embodiments of features of the disclosure. These figures are illustrative and are not intended to be limiting.

FIG. 1 is a block circuit diagram of a control circuit to activate a switch according to an embodiment of the present disclosure;

FIG. 2 is a further detailed block circuit diagram of the control circuit of FIG. 1, according to an embodiment of the present disclosure;

FIG. 3A is a signal diagram of the sinusoidal wave output from an AC power source of the block circuit diagram of FIG. 1, according to an embodiment of the present disclosure;

FIG. 3B is a signal diagram of the ZC_DETECT block of the block circuit diagram of FIG. 2, according to an embodiment of the present disclosure;

FIG. 3C are overlapping signal diagrams for V_{BANK} and POWER of the block circuit diagram of FIG. 1, according to an embodiment of the present disclosure;

FIG. 4A is an enlarged view of the signal diagrams for V_{BANK} and POWER taken along the lines shown in FIG. 3C, according to an embodiment of the present disclosure;

FIG. 4B is a signal diagram of the voltage V_{GS} across the FET FILTER block of the block circuit diagram of FIG. 1;

FIG. 4C is a signal diagram of the FET_EN block of the block circuit diagram of FIG. 2, according to an embodiment of the present disclosure;

FIG. 4D is a signal diagram of the FET_CMD1 block of the block circuit diagram of FIG. 2, according to an embodiment of the present disclosure;

FIG. 4E is a signal diagram of the FET_CMD2 block of the block circuit diagram of FIG. 2, according to an embodiment of the present disclosure;

FIG. 4F is a signal diagram of the TRIAC_Q1 block of the block circuit diagram of FIG. 2, according to an embodiment of the present disclosure;

FIG. 5A is an enlarged view of the signal diagram of the ZC_DETECT block of FIG. 3B, according to an embodiment of the present disclosure;

FIG. 5B is an enlarged view of the signal diagram for POWER taken along the lines shown in FIG. 3C, according to an embodiment of the present disclosure; and,

FIG. 5C is a signal diagram of the TRIAC_Q3 block of the block circuit diagram of FIG. 2, according to an embodiment of the present disclosure.

### DETAILED DESCRIPTION

The following embodiments are merely illustrative and are not intended to be limiting. It will be appreciated that various modifications and/or alterations to the embodiments described herein may be made without departing from the disclosure and any modifications and/or alterations are within the scope of the contemplated disclosure.

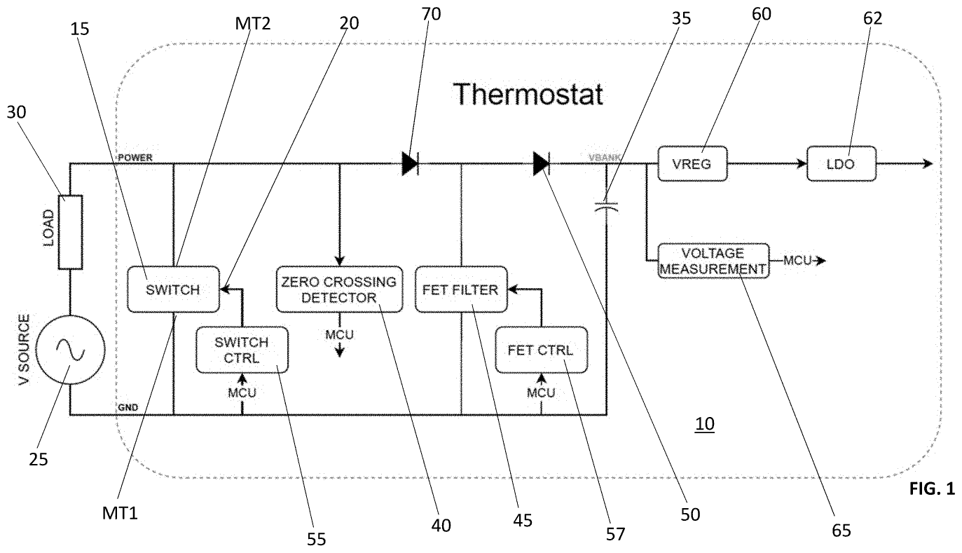

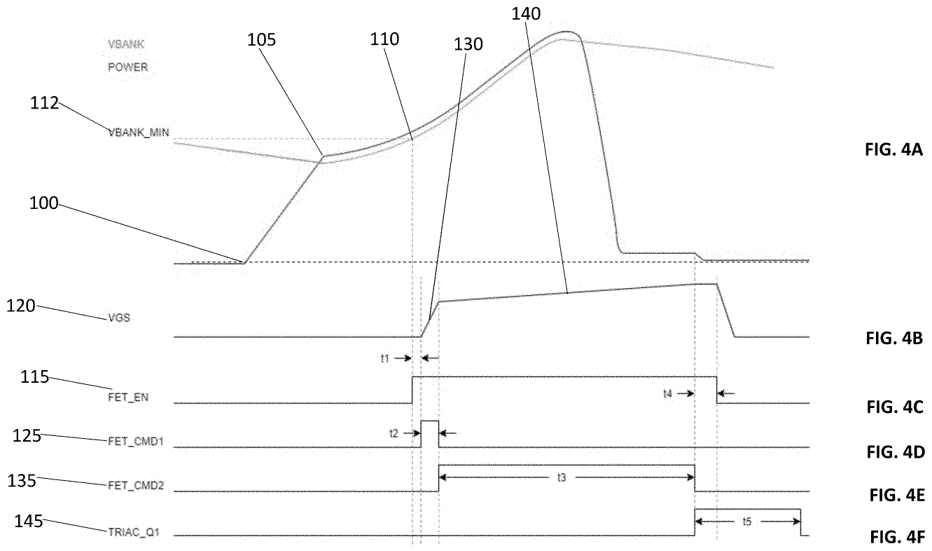

With reference to FIG. 1 and according to an embodiment of the present disclosure, a block diagram is shown illustrating an improved control circuit 10 for activating a switch 15 and powering a load 30. In a preferred embodiment, the load 30 is a baseboard heater, although other types of loads are possible, such as fan forced heaters or other types of convectors, etc. A worker skilled in the art would also appreciate that in a preferred embodiment, the switch 15 is a TRIAC; however, other switches, such as an IGBT, MOSFET or relay could also be used. It is known that TRIAC switches such as the switch 15 described are comprised of first and second anodes A1, A2 also known as Main Terminal 1 (MT1) and Main Terminal 2 (MT2), respectively, and a gate 20. The switch 15 is capable of switching from a first non-conducting state to a second conducting state, depending on a current received at the gate 20, better known in the art as the trigger current. When the switch 15 is in the second conducting state, current flows from the source 25 to the load 30. When the switch 15 is in the first non-conducting state, current does not flow from the source 25 to the load 30. However, voltage from the source 25 is still present at terminals MT1 and Mt2 of the switch 15. It is an object of the present circuit 10 to utilize this voltage, when the switch 15 is in the first non-conducting state, to charge an energy bank with voltage V_{BANK}. In the present embodiment, the energy bank is a capacitor 35, although other electrical storage devices may be used. A worker skilled in the art would appreciate that the present circuit 10 is typically used to power a device such as a thermostat. Instead of having a dedicated power line to power the thermostat, the present circuit 10 provides for “power stealing” by charging the capacitor 35 when the switch 15 is in the first non-conducting state. In turn, the charged capacitor 35 is utilized to power the thermostat when the switch 15 is in the second conducting state. The circuit 10 is further comprised of a zero-crossing (ZC) detection circuit 40. A purpose of the ZC detection circuit 40 is to detect the zero-crossing of the power source 25. As shown, the circuit 10 is further comprised of a slow linear switch (SLS) 45 in parallel with the switch 15. In a preferred embodiment, the SLS 45 is a field-effect transistor (FET), although other switches may be used, such as a bipolar junction transistor (BJT). A purpose of the SLS 45 is to allow current from the source 25 to flow to the load 30 in a slow, progressive manner (i.e. non-instantaneously) until the switch 15 can take over, thereby reducing conducted electromagnetic interference (EMI) generated by the switch 15. Indeed, it is a problem in the art that when the switch 15 transitions from the first non-conducting state to the second conducting state instantaneously, the current as seen by the load 30 changes rapidly (this phenomenon is described as high di/dt), which creates the unwanted conducted EMI. As such, it is an object of the present disclosure to minimize as much as possible such instantaneous di/dt as seen by the load 30. The circuit 10 is further comprised of a diode 50 to ensure that the capacitor 35 does not discharge when the voltage across the switch 15 or the SLS 45 becomes inferior to the voltage across the capacitor 35. Although a diode 50 is shown, a worker skilled in the art would appreciate that the diode 50 may be replaced with equivalent active circuitry to ensure that the capacitor 35 does not discharge when the voltage across the switch 15 or the SLS 45 becomes inferior to the voltage across the capacitor. A worker skilled in the art would further appreciate that the switch 15 is comprised of a switch activation circuit 55, while the SLS 45 is comprised of a SLS activation circuit 57. A voltage regulator 60 and a low-dropout regulator 62 are shown to maintain steady voltage V_{CC}. Although the low-dropout regulator 62 is shown, a worker skilled in the art would appreciate that a switching voltage regulator may be used. A voltage measurement circuit 65 is also present, electrically connected to the capacitor 35 to measure its voltage. A purpose of the voltage measurement circuit 65 is to detect for voltage VBANK_MIN (shown as 112 in FIG. 4A), which is the minimum threshold value of the capacitor 35 before power stealing is required. A half wave rectifier diode 70 is also shown. A worker skilled in the art would appreciate that a purpose of the diode 70 is to protect the SLS 45 by eliminating any current from passing through the SLS 45 during the negative half wave of the power source 25. Although not shown, a worker skilled in the art would appreciate that the present control circuit 10 may also be comprised of a capacitor (not shown) in parallel electrical connection with the switch 15. A purpose of this optional capacitor (not shown) would be to assist in the filtering of conducted EMI.

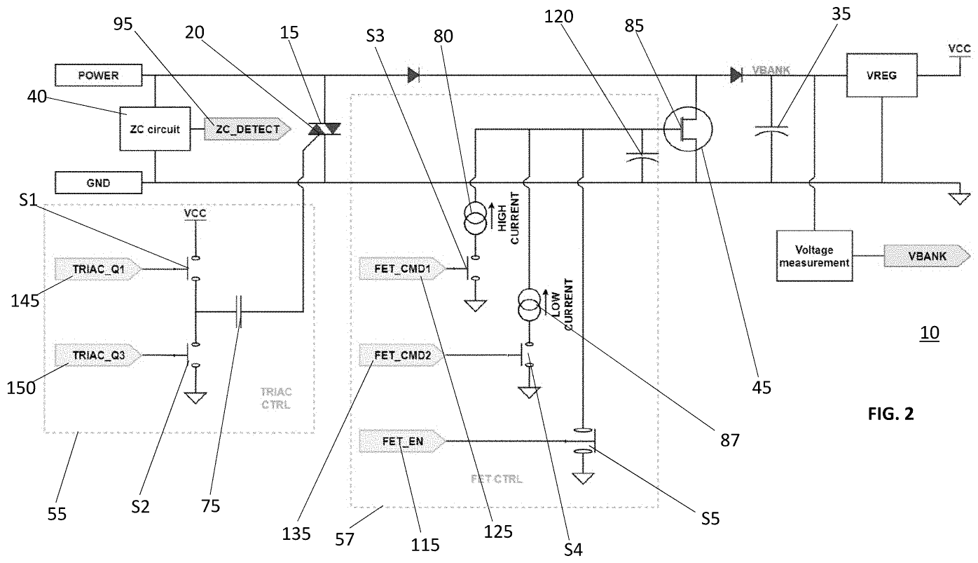

With reference to FIG. 2 and according to an embodiment of the present disclosure, the control circuit 10 is shown in greater detail. More specifically, the control circuit 10 is shown with the switch activation circuit 55 and the SLS activation circuit 57. The switch activation circuit 55 is further preferably comprised of first and second control switches S1, S2 electrically connected to a resistor (not shown) series connected to a capacitor 75, in turn connected to the gate 20 of the switch 15. A purpose of the resistor (not shown) is to limit the current flowing to the capacitor 75. Each one of the switches S1, S2 are configured to receive a pulse signal from a controller (not shown), the controller (not shown) sending either pulse TRIAC_Q1 145 for switch S1 or pulse TRIAC_Q3 150 for switch S2. The SLS activation circuit 57 is further preferably comprised of third, fourth and fifth control switches S3, S4, S5. The third switch S3 is electrically connected to a high current source 80, which is in turn connected to the gate 85 of the SLS 45. The fourth switch S4 is electrically connected to a low current source 87, which is also in turn connected to the gate 85 of the SLS 45. The fifth switch S5 is electrically connected directly to the gate 85 of the SLS 45. A worker skilled in the art would appreciate that FET_CMD1 125 is a pulse from a controller (not shown) to turn the switch S3 on, FET_CMD2 135 is a pulse from a controller (not shown) to turn the switch S4 on, and FET_EN 115 is a pulse from a controller (not shown) to turn the switch S5 on. A worker skilled in the art would further appreciate that the switch activation circuit 55 and the SLS activation circuit 57 are merely preferred embodiment within the control circuit 10. Indeed, other types of activation circuits are possible, provided that the SLS 45 is activated slowly to minimize abrupt current variations di/dt of the circuit 10.

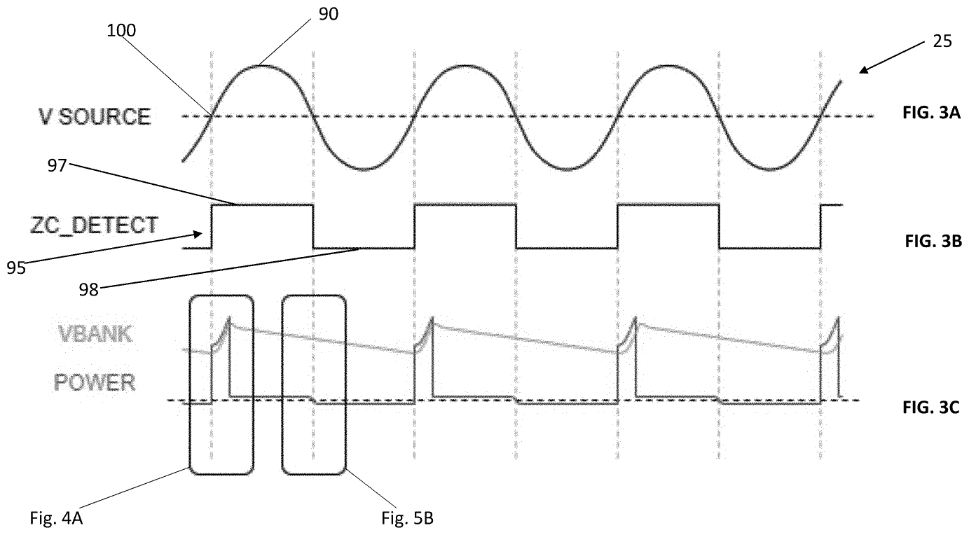

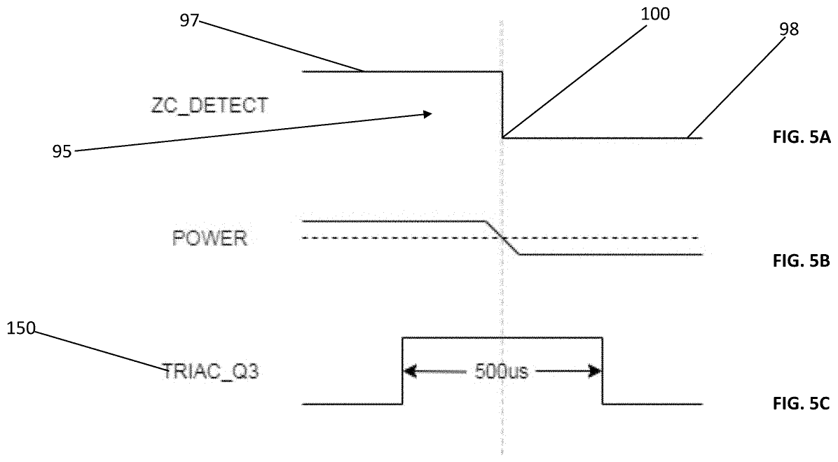

With reference to FIGS. 3A, 3B and 3C and according to an embodiment of the present disclosure, the voltage across V_{BANK} and POWER are shown in greater detail. With specific reference to FIG. 3A, a sinusoidal wave 90 of the power source 25 is shown. With specific reference to FIG. 3B, a corresponding ZC detect signal 95 is shown. A worker skilled in the art would appreciate that the ZC detect signal 95 can be toggled between a high state 97 and a low state 98. As the ZC detection circuit (not shown) monitors a zero-crossing 100 of the source 25, the ZC detect signal 95 is toggled to a high state 97 for every positive half wave of the source 25, and to a low state 98 for every negative half wave of the source 25. Indeed, the present control circuit (not shown) only activates the SLS (not shown) on positive half cycles of the source 25, such that the ZC detect signal 95 is only correspondingly toggled at the high state 97 every positive cycle after the zero-crossing 100 of the source 25. As will be further described below, the switch (not shown) is only activated after the activation of the SLS (not shown) to minimize conducted EMI. This activation is shown by corresponding voltages V_{BANK} and POWER in FIG. 3C and specifically within the line designated as FIG. 4A. To ensure continued conduction of the switch (not shown) for the following half cycle of the power source 25, the control circuit (not shown) emits a pulse (not shown) for a short period of time before and after the next zero-crossing 100. The corresponding voltages V_{BANK} and POWER are shown in FIG. 3C and specifically within the line designated as FIG. 5B.

With reference to FIGS. 2, 4A, 4B, 4C, 4D and 4E and according to an embodiment of the present disclosure, various signal diagrams are shown. At a first time being at the zero crossing 100, the ZC detection circuit 40 detects a zero-crossing 100 of the sinusoidal wave of the power source (not shown). At this zero crossing 100, a corresponding ZC detect signal 95 is emitted. The control circuit 10 is now operating in this half cycle of the sinusoidal wave of the power source (not shown). At a second time 105, the voltage seen at POWER is approximately the sinusoidal wave of the power source (not shown). A worker skilled in the art would appreciate that this time difference between the zero crossing 100 and the second time 105 is required to allow the voltage POWER to surpass and therefore be able to charge V_{BANK}. After the second time 105, the capacitor 35 is being charged with power from the source (not shown), termed V_{BANK}. The control circuit 10 continuously monitors the value V_{BANK} to determine when a minimum value of V_{BANK}, termed VBANK_MIN 112, is achieved, which occurs at a third time 110. A worker skilled in the art will appreciate that the VBANK_MIN 112 value is the minimum voltage required to power the control circuit 10 for an entire cycle of the sinusoidal wave of the power source (not shown). Once this minimum threshold VBANK_MIN 112 is met, FET_EN 115 is emitted, which activates switch S5. In turn, this allows a capacitor 120 positioned at the gate 85 of the SLS 45 to begin to charge. Indeed, it is an object of the present disclosure that the gate-source voltage (known in the art as V_{GS}) of the SLS 45 be 0V when FET_EN 115 is deactivated. This ensures that the SLS 45 is not activated accidentally. After a period of time t1, the control circuit 10 activates FET_CMD1 125 to turn it on for a period of time t2. During this period of time t2, the capacitor 120 is charged rapidly, as shown by the corresponding steep V_{GS} slope 130 in FIG. 4B. The control circuit 10 provides for the capacitor 120 to charge rapidly during this period of time t2 as the SLS 45 is not yet activated. Indeed, the SLS 45 is not activated until the voltage V_{GS} becomes greater than the threshold voltage of the SLS 45. A worker skilled in the art would appreciate that such threshold voltage is termed V_{TH}, such that the SLS 45 is activated once V_{GS}>V_{TH}. After the period of time t2, FET_CMD1 125 is deactivated and FET_CMD2 135 is emitted for a period of time t3. During this period of time t3, the capacitor 120 is charged slowly and gradually, which correspondingly slowly and gradually increases the voltage across V_{GS}, as shown by the corresponding V_{GS} slope 140 in FIG. 4B. In other words, during the interval of time t3, V_{GS} will become grater than V_{TH} such that at the end of the period of time t3, the SLS 45 will be activated and thus conducting. A purpose of the control circuit 10 is to activate the SLS 45 slowly and gradually to minimize conducted EMI generated by the control circuit 10. At the end of the period of time t3, FET_CMD2 135 is deactivated and TRIAC_Q1 145 is emitted for a period of time t5. Turning on TRIAC_Q1 145 correspondingly actuates the switch 15, from the first non-conducting state to the second conducting state, and current no longer flows from the power source (not shown) through the SLS 45. It is an object of the present disclosure to activate the switch 15 in this manner to reduce conducted EMI. Indeed, after a period of time t4 that TRIAC_Q1 145 is emitting, FET_EN 115 is deactivated as the SLS 45 is no longer needed to conduct. A worker skilled in the art would appreciate that although the SLS 45 and switch 15 may be activated using the pulses shown in FIGS. 4C to 4F, other types of activation means are possible without departing from the scope of the present disclosure. Indeed, other types of switch and SLS activation circuits 55, 57 are possible, provided that the SLS 45 is actuated around the zero-crossing, slowly and gradually until the SLS 45 is fully saturated before then actuating the switch 15, which minimizes abrupt current variations di/dt of the circuit 10.

With reference to FIGS. 2, 5A, 5B and 5C and according to an embodiment of the present disclosure, various signal diagrams are shown. Before the next zero-crossing 100 of the power source 25, as detected by the zero-crossing detector 40, a pulse TRIAC_Q3 150 is emitted, until a short time after the zero-crossing 100, as shown in FIG. 5C. This pulse TRIAC_Q3 ensures that the switch 15 remains conducting such that the load (not shown) remains powered. The voltage across POWER is shown specifically in FIG. 5B. A worker skilled in the art would appreciate that although 500 μs is shown in FIG. 5C, other suitable times may be utilized without departing from the scope of the disclosure. A worker skilled in the art would also appreciate that upon such zero-crossing 100 of the source 25, the ZC detect signal 95 is toggled from the high state 97 to a low state 98.

With further reference to FIGS. 1, 2 and 3A and according to an embodiment of the present disclosure, the switch 15 may be activated by detecting a zero-crossing 100 of the power source 25, actuating the SLS 45 after the zero-crossing 100 of the power source 25 and actuating the switch 15 after the SLS 45 is completely saturated. Doing so will lead to reduced conducted EMI of the control circuit 10. In the preferred embodiment, the capacitor 120 is charged slowly and gradually, which correspondingly slowly and gradually increases the voltage across V_{GS}. Activating the SLS 45 slowly and gradually in this manner will minimize conducted EMI generated by the control circuit 10.

Many modifications of the embodiments described herein as well as other embodiments may be evident to a person skilled in the art having the benefit of the teachings presented in the foregoing description and associated drawings. It is understood that these modifications and additional embodiments are captured within the scope of the contemplated disclosure which is not to be limited to the specific embodiment disclosed.

1. A control circuit to control power to a load, comprising:
a first switch connected to a power source, the switch configured to switch from a first non-conducting state to a second conducting state;
an energy bank electrically connected to the first switch, the energy bank to store energy and power a device when the first switch is in the second conducting state;
a zero-crossing (ZC) detection circuit electrically connected to detect a zero-crossing of the power source,
a second switch in parallel electrical connection with the first switch, the slow linear switch activated after the zero-crossing of the power source.

2. The control circuit of claim 1 wherein the first switch is a triode for alternating current (TRIAC).

3. The control circuit of claim 1 wherein the first switch is further comprised of a switch activation circuit.

4. The control circuit of claim 1 wherein the slow linear switch is further comprised of an SLS activation circuit.

5. The control circuit of claim 1 further comprised of a diode electrically connected to the slow linear switch to ensure that the energy bank does not discharge when the slow linear switch is activated.

6. The control circuit of claim 1 further comprised of a half wave rectifier diode.

7. The control circuit of claim 1 wherein the slow linear switch is actuated before the first switch switches from the first non-conducting state to the second conducting state to reduce conducted electromagnetic interference of the control circuit.

8. The control circuit of claim 7 further comprised of a second energy bank connected in between a gate and a source of the slow linear switch.

9. The control circuit of claim 7 wherein the slow linear switch is activated during a period of time, whereby a voltage V_{GS} of the slow linear switch is increasing slowly to reduce conducted electromagnetic interference of the control circuit.

10. A method of activating a first switch, the steps comprising:
detecting a zero-crossing of a power source;
actuating a second switch after the zero-crossing of the power source; and,
actuating the first switch after the second switch is completely saturated to reduce conducted electromagnetic interference of a control circuit.

11. The method of claim 10 wherein the second switch is a slow linear switch.

12. The method of claim 10 wherein the second switch is actuated before the first switch switches from the first non-conducting state to the second conducting state.

13. The method of claim 10 wherein the second switch is activated during a period of time, whereby a voltage V_{GS} of the second switch gradually increases.
